(19) United States
(12) Patent Application Publication
(10) Pub. No.: US 2014/0175586 A1
(43) Pub. Date: Jun. 26, 2014

(54) IMAGE SENSOR AND METHOD FOR FABRICATING THE SAME

(71) Applicant: SK HYNIX INC., Gyeonggi-do (KR)

(72) Inventors: Sang-Sik KIM, Gyeonggi-do (KR); Seung-Jeong SEO, Gyeonggi-do (KR); Sun-Tae KIM, Gyeonggi-do (KR)

(73) Assignee: SK HYNIX INC., Gyeonggi-do (KR)

(21) Appl. No.: 13/827,684

(22) Filed: Mar. 14, 2013

(30) Foreign Application Priority Data
Dec. 26, 2012 (KR) 10-2012-0153824

(51) Int. Cl. H01L 27/146

(52) U.S. Cl. CPC H01L 27/14625
USPC 257/432

(57) ABSTRACT

An image sensor and a method for fabricating the image sensor are provided. The image sensor includes a substrate having a plurality of unit pixel regions. A light absorption layer is formed on the substrate. A plurality of overlapping color filters are formed on the light absorbing layer.

### CROSS-REFERENCE TO RELATED APPLICATIONS

The present application claims priority of Korean Patent Application No. 10-2012-0153824, filed on Dec. 26, 2012, which is incorporated herein by reference in its entirety.

### BACKGROUND

1. Field

Exemplary embodiments of the present invention relate to a semiconductor device fabrication technology, and more particularly, to an image sensor and a method for fabricating the image sensor.

2. Description of the Related Art

Complementary Metal Oxide Semiconductor (CMOS) image sensors (CIS) are semiconductor devices for transforming an optical image into electrical signals. Adopting a switching scheme, the semiconductor devices include MOS transistors formed as many as pixels by using CMOS technology that uses a control circuit and a signal processing circuit as peripheral circuits and detect output signals by using the MOS transistors. The CMOS image sensors are divided into Front Side Illumination Image Sensors and Back Side Illumination Image Sensors

In the front side illumination image sensors, light enters the upper part, passes through a micro-lens, a color filter, and a signal generation circuit, and enters a light receiving device of a substrate. In this case, as the number of pixels of the image sensor becomes small, the light is more affected by the signal generation circuit. Therefore, the signal generation circuit becomes small and an optical crosstalk phenomenon occurs. Also, in the back side illumination image sensors, light passes through a micro-lens and a color filter, and enters a light receiving device of a substrate. Therefore, the influence of a signal generation circuit can be eliminated, and since there is no interlayer dielectric layer, photo-sensitivity is improved. However, since unit pixel regions are not properly isolated from each other, the optical crosstalk phenomenon occurs.

### SUMMARY

An image sensor, comprising a substrate including a plurality of unit pixel regions; a light absorption layer formed on the substrate; and a plurality of color filters formed on the substrate, wherein at least one of the plurality color filters is formed over the light absorbing layer, wherein the plurality of color filters include a first color filter and a second color filter, and wherein the first color filter overlaps an end of the second color filter.

An image sensor, comprising a substrate including plurality of unit pixel regions; a light absorption layer formed on the substrate; and a plurality of color filters formed on the substrate, wherein at least some of the plurality of color filters are formed over the light absorption layer, wherein the plurality of color filters include a first color filter, a second color filter, and a third color filter.

A method for fabricating an image sensor, comprising forming a light absorption layer on a substrate having a plurality of unit pixel regions; and forming a plurality of color filters on the substrate, wherein over the light absorption layer wherein at least some of the plurality of color filters are formed over the light absorption layer, wherein the plurality of color filters include a first color filter, a second color filter, and a third color filter.

Each color filter, of the plurality of color filters, may have a line width that is greater than a line width of the unit pixel regions.

The first color filter may include a blue color filter, and the second color filter may include a green color filter.

The first color filter may include a green color filter, and the second color filter may include a red color filter.

The first color filter may include a blue color filter, the second color filter may include a green color filter, and the third color filter may include a red color filter

The forming of the plurality of color filters may further comprises simultaneously forming the light absorption layer along boundaries of the unit pixel regions and forming the first color filter, forming the second color filter to overlap the light absorption layer and an end of the first color filter, and forming the third color filter to overlap the light absorption layer and an end of the second color filter.

The plurality of color filters and the light absorption layer are formed through an exposure and development process.

A height of the first color filter may be lower than a height of the second color filter, and the height of the second color filter may be less than a height of the third color filter.

Each color filter, of the plurality of color filters, may have a line width that is greater than a line width of the unit pixel regions.

The light absorption layer may be formed along boundaries of the unit pixel regions.

The light absorption layer may have a grid pattern.

The light absorption layer may contact a sidewall of the first color filter and overlap ends of the second color filter and the third color filter.

A height of the light absorption layer may be the same as a height of a sidewall of the first color filter, and the height of the light absorption layer may be less than heights of the second color filter and the third color filter.

The light absorption layer may include a same material as a material of the first color filter.

The first color filter may include a blue color filter, the second color filter may include a green color filter, and the third color filter may include a red color filter.

### BRIEF DESCRIPTION OF THE DRAWINGS

FIG. 1 is a cross-sectional view illustrating an image sensor in accordance with an exemplary embodiment.

FIG. 2 is a plan view illustrating a color filter and a light absorption layer of an exemplary image sensor.

FIGS. 3A to 3E are cross-sectional views illustrating a method of fabricating an exemplary image sensor.

FIGS. 4A to 4D are plan views illustrating the color filter and the light absorption layer fabricated according to an exemplary method.

FIG. 5 is a cross-sectional view illustrating an image sensor in accordance with an exemplary embodiment.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being on a second layer or “on” a substrate, it not only refers to a case where the first layer is formed directly on the second layer or the substrate but also a case where a third layer exists between the first layer and the second layer or the substrate.

An exemplary embodiment may be applied to both front side illumination image sensors and back side illumination image sensors. However, the case of applying the technology to the back side illumination image sensors is described, herein, for the sake of convenience in description.

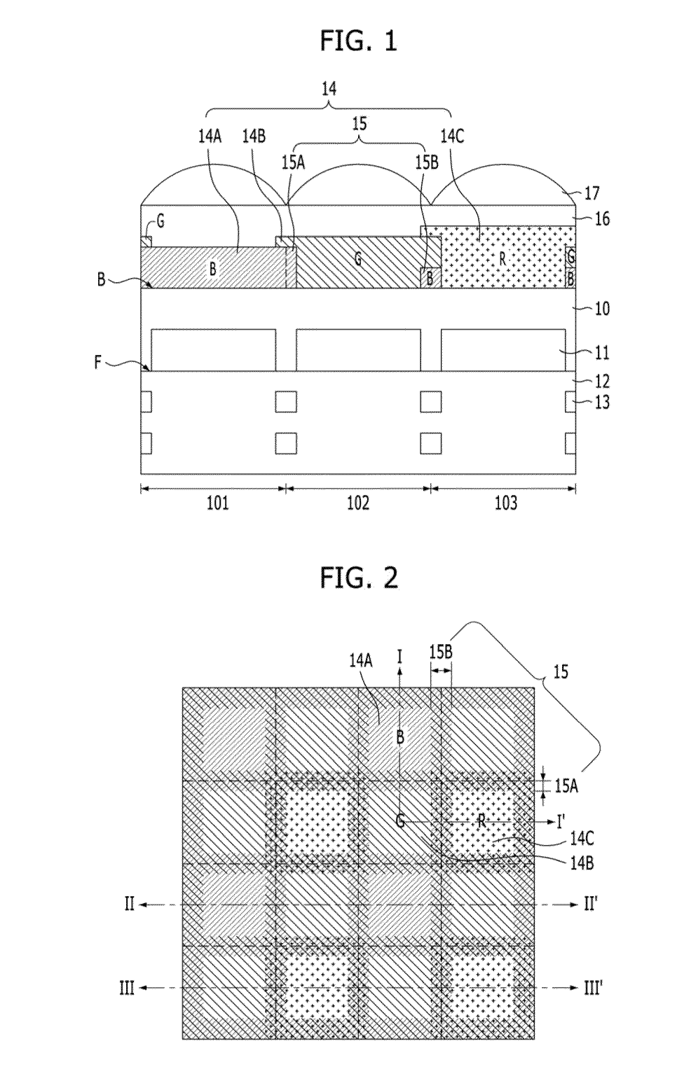

FIG. 1 is a cross-sectional view illustrating are exemplary image sensor.

Referring to FIG. 1, an exemplary image sensor includes a substrate 10 having a plurality of unit pixel regions 101, 102, and 103, a plurality of light receiving devices 11 formed in the substrate 10, an interlayer dielectric layer 12 formed on the front side F of the substrate 10 and including a signal generation circuit 13, a plurality of color filters 14 formed on the back side B of the substrate 10, which is the opposite side to the front side F, a light absorption layer 15 formed on the back side of the substrate 10 under the color filters 14, a planarization layer 16 covering the color filters 14 on the back side of the substrate 10, and micro-lenses 17 formed on the planarization layer 16.

The substrate 10 including the unit pixel regions 101, 102 and 103 may include a single crystalline material. The substrate 10 may include a silicon-containing material. Therefore, the substrate 10 may include single crystalline silicon.

The light receiving devices 11 are formed on the substrate 10 over the unit pixel regions 101, 102 and 103. The light receiving devices 11 may include photodiodes (PD). The photodiodes generate photocharges by using received light.

Subsequently, the light receiving devices 11 and an isolation layer (not shown) for isolating the light receiving devices 11 from each other may be formed on the substrate 10.

The interlayer dielectric layer 12 is formed on the front side F of the substrate 10, and the signal generation circuit 13 is formed inside the interlayer dielectric layer 12. The signal generation circuit 13 generates electrical signals corresponding to the charges generated by the light receiving devices 11. The signal generation circuit may include a plurality of layers of conductive lines and a plurality of transistors formed inside of the interlayer dielectric layer 12. The plurality of transistors may include a transfer transistor, a reset transistor, a source follower transistor, a select transistor, or a bias transistor. Also, the plurality of layers of conductive lines may be electrically connected to each other or may be electrically connected to the plurality of transistors through plugs.

The color filters 14 are formed on the back side B of the substrate 10. The color filters 14 may be formed corresponding to the unit pixel regions 101, 102, and 103. The color filters 14 may have a structure where both ends of each color filter overlap those of the other color filters so as to have a stepped height. The color filters 14 may include the light absorption layer 15.

The color filters 14 may include a plurality of first color filters 14A, a plurality of second color filters 14B, and a plurality of third color filters 14C. A color filter 14A may overlap a second color filter 14B, and the second color filter 14B may overlap the first color filter 14A and a third color filter 14C. The third color filter 14C may overlap the second color filter 14B. The first color filters 14A may be partially overlapped with the light absorption layer 15, and the light absorption layer 15 may be formed to be partially overlapped on a sidewall of the first color filter 14A. The second color filter 14B and the third color filter 14C may overlap the light absorption layer 15.

The color filters 14 may have an RGB structure. For example, the plurality of first color filters 14A may include blue color filters, the plurality of second co or filters 14B may include green color filters, and the plurality of third color filters 14C may include red color filters.

Each of the pluralities of first color filters 14A, second color filters 14B, and third color filters 14C may have a line width greater than a line width of the unit pixel regions 101, 102, and 103. Conventional color filters may have a line width that is less than or equal to a line width of each unit pixel. In contrast, each of the pluralities of first color filters 14A, second color filters 14B, and third color filters 14C have a line width that greater than the line width of a conventional color filter because the pluralities of first to third color filters 14A, 14B and 14C overlap and include the light absorption layer 15.

The light absorption layer 15 is formed on the back side B of the substrate 10 under the color filters 14. The light absorption layer 15 is formed along a boundary of the unit pixel regions 101, 102, and 103. The light absorption layer 15 may include a first light absorption layer 15A and a second light absorption layer 15B. The first light absorption layer 15A may be formed on a sidewall of each of the plurality of first color filters 14A. The second light absorption layer 15B may be formed to overlap ends of subsequent second and third color filters 14B and 14C of the pluralities of second and third color filters 14B and 14C. This structure will be described later in detail with reference to FIG. 2.

The first light absorption layer 15A may be as high as the first color filters 14A, and the second light absorption layer 15B may be lower than the first color filters 14A in height.

The light absorption layer 15 may be formed of any materials that may absorb visible lights. In an exemplary embodiment, the light absorption layer 15 may be formed of the same material as the first color filters 14A. For example, when the first color filters 14A include a blue color filter, the light absorption layer 15 may include a blue color filter.

The planarization layer 16 is formed over the color filters 14. The planarization layer 16 may be formed of an oxide layer, a nitride layer, or an oxynitride layer. The hemispheric micro-lenses 17 are formed over the planarization layer 16 to respectively correspond to the unit pixel regions 101, 102, and 103. The micro-lenses 17 may be formed to be spaced apart from each other to obtain optical shading characteristics.

FIG. 2 is a plan view illustrating a color filter and a light absorption layer of an exemplary image sensor The cross section taken along the I-I′ line of FIG. 2 is shown in FIG. 1.

Referring to FIG. 2, the color filters 14 are formed in the upper portion of the substrate 10. The color filters 14 may include the plurality of first color filters 14A, the plurality of second color filters 14B, and the plurality of third color filters 14C. The color filters 14 may have a Red Green Blue (RGB) structure. The color filters 14 may include a plurality of red color filters, a plurality of green color filters, and a plurality of blue color filters. For example, the plurality of first color filters 14A may include blue color filters, the plurality of second color filters 14B may include green color filters, and the plurality of third color filters 14C may include red color filters.

The color filters 14 may be partially overlapped with the light absorption layer 15. The plurality of first color filters 14A contact a sidewall of the light absorption layer 15, and the pluralities of second and third color filters 14B and 14C overlap the light absorption layer 15.

The light absorption layer 15 is formed in a grid pattern along a boundary of the unit pixel regions 101, 102, and 103. The light absorption layer 15 may include the same materials as that of the first color filters 14A.

Meanwhile, as illustrated in FIG. 2, to describe the dispositions of the light absorption layer 15 according to the cutting lines I-I′, II-II′, and the light absorption layer 15 is disposed along the boundary of the unit pixel regions 101, 202, and 103. In other words, since the light absorption layer 15 is disposed in a grid pattern, even though the image sensor is cut in the I-I′, II-II′ and III-III′ lines, there is the light absorption layer 15 disposed.

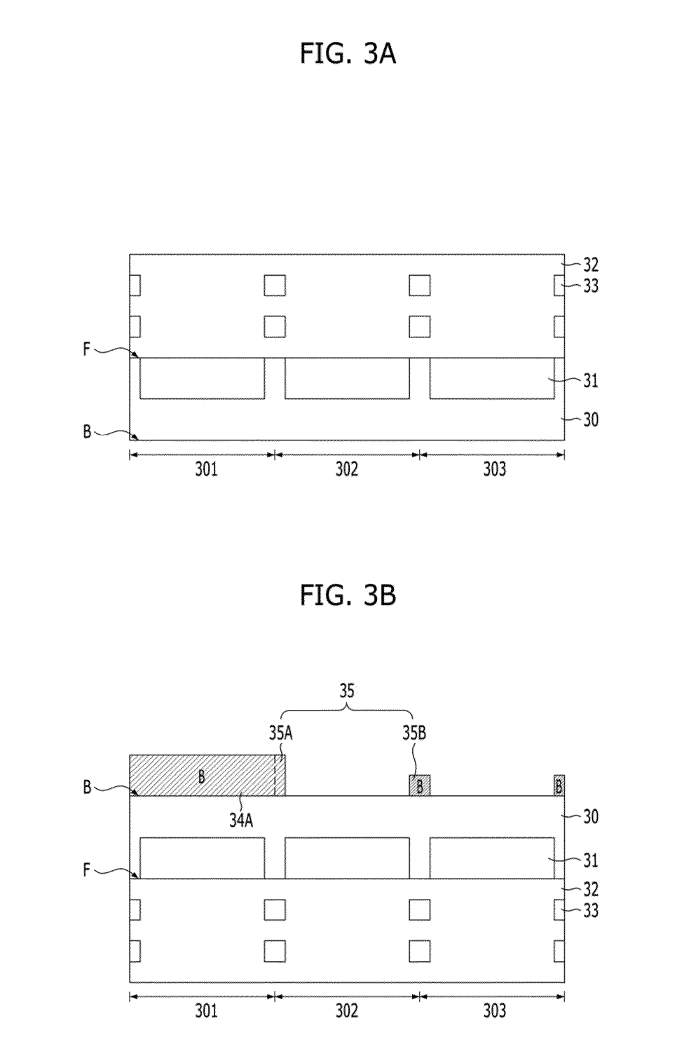

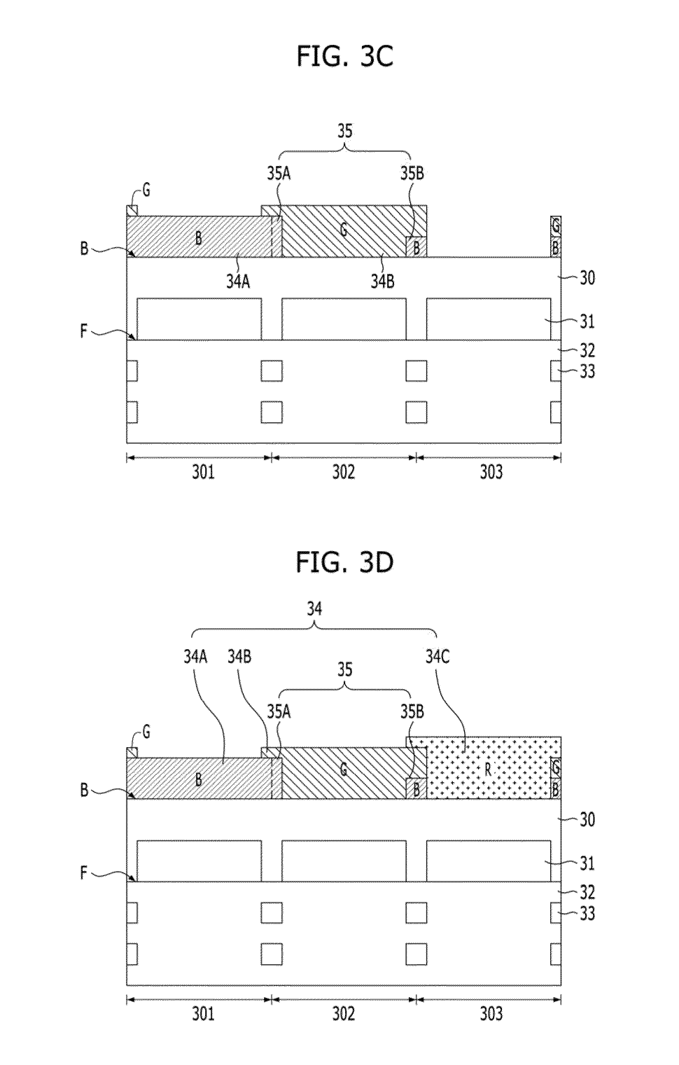

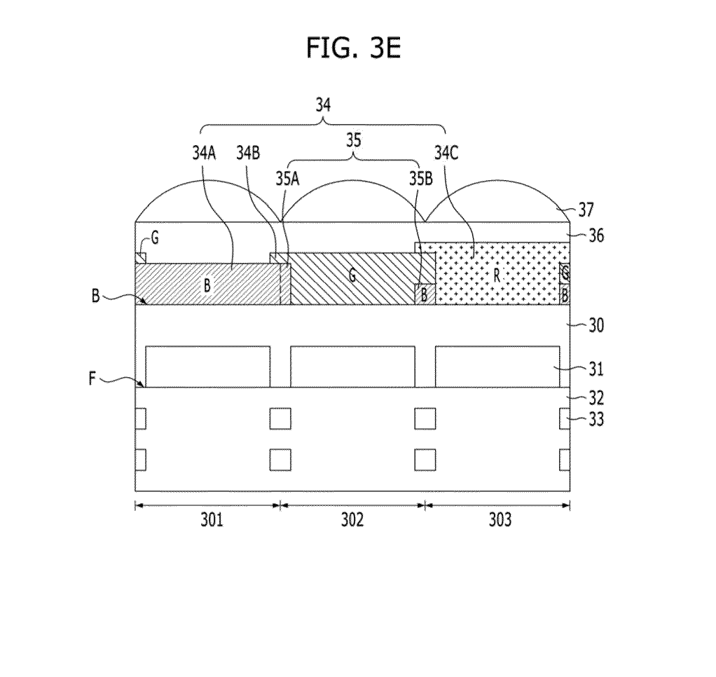

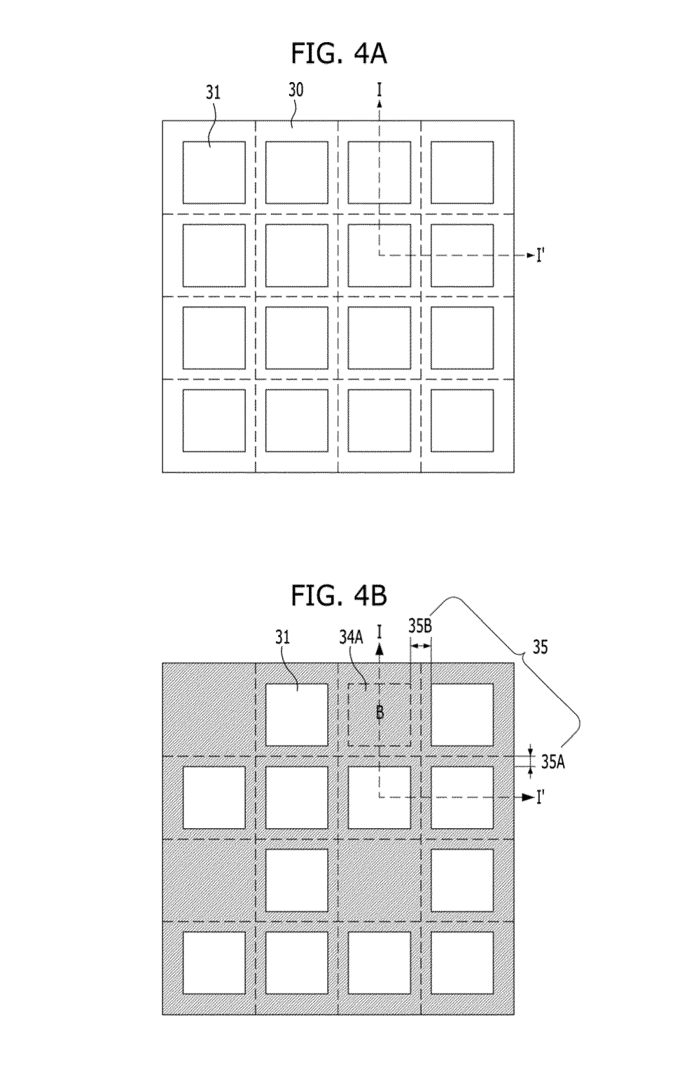

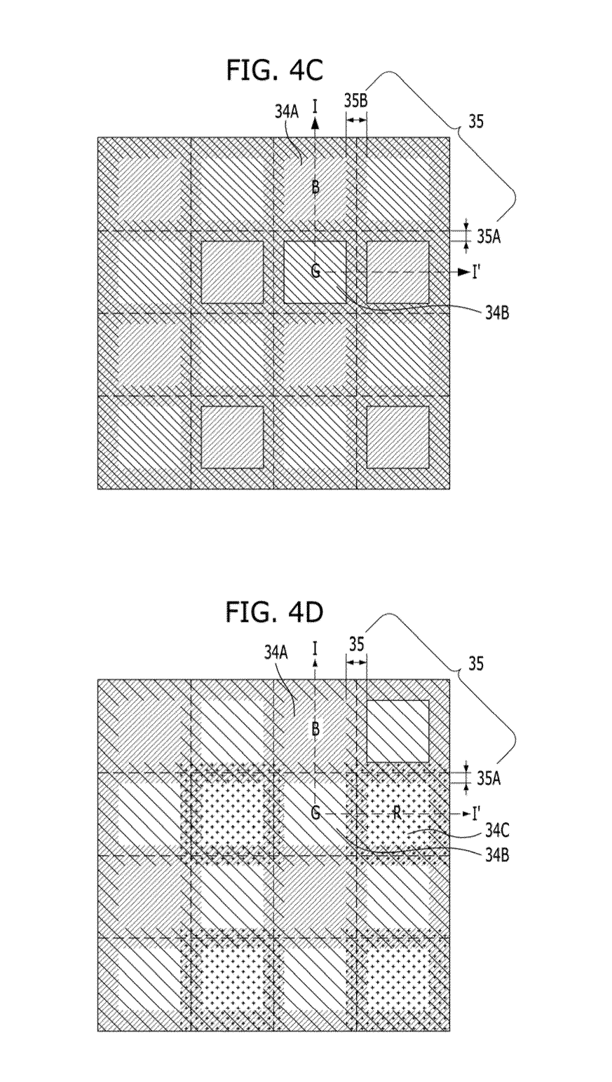

FIGS. 3A to 3E are cross-sectional views illustrating an exemplary method for fabricating the image sensor shown in FIGS. 1 and 2. FIGS. 4A to 4D are plan views illustrating the color filters 14 and the light absorption layer 15 fabricated according to the method shown in FIGS. 3A to 3E. FIGS. 3A to 3D are cross-sectional views of the image sensor shown in FIGS. 4A to 4D taken along the line. FIG. 3E is a cross section of the image sensor shown in FIG. 4D further including a planarization layer and micro-lenses.

As illustrated in FIGS. 3A and 4A, a substrate 30 including a plurality of unit pixel regions 301, 302, and 303 is provided. The substrate 30 may include a single crystalline material. The substrate may include a silicon-containing material. Therefore, the substrate 30 may include single crystalline silicon.

Subsequently, an isolation layer (not shown) for isolating the light receiving devices from a plurality of light receiving devices 31, which are to be formed in a subsequent process, is formed in the substrate 30. The isolation layer may be formed through a Shallow Trench Isolation (STI) process. The STI process is a series of processes of forming trenches for device isolation in the substrate 30 and filling the inside of the trenches with an insulation material so as to form the isolation layer.

Subsequently, a plurality of light receiving devices 31 corresponding to the unit pixel regions are formed in the substrate 30. The light receiving devices 31 may include photodiodes (PD). The photodiodes generate photocharges by using received light.

Subsequently, an interlayer dielectric layer 32 is formed on the front side F of the substrate 30 including the light receiving devices 31. A signal generation circuit 33 generates electrical signal's corresponding to the charges generated in the light receiving devices 31. The signal generation circuit 33 may include a plurality of conductive lines and a plurality of transistors formed inside the interlayer dielectric layer 32. The plurality of transistors may include a transfer transistor, a reset transistor, a source follower transistor, a select transistor, or a bias transistor. Also, the plurality of conductive lines may be electrically connected to each other or may be electrically connected to the plurality of transistors through plugs.

Referring to FIGS. 3B and 4B, a grinding process is performed on the back side B of the substrate 30. The grinding process is performed to increase light condensation efficiency by decreasing the passing route of light entering the light receiving devices 31 from the back side B of the substrate 30.

Subsequently, a post-process is performed to cure the defects caused by the grinding process on the back side B of the substrate 30. The post-process may be a thermal treatment performed in an oxygen atmosphere.

Subsequently, a plurality of first color filters 34A are formed on the back side B of the substrate 30. At the same time, a light absorption layer 35 is formed. The light absorption layer 35 prevents an optical crosstalk phenomenon between adjacent unit pixel regions.

The plurality of first color filters 34A may be formed corresponding to the unit pixel regions, and the light absorption layer 35 may be formed along the boundary of the unit pixel regions 301, 302, and 303. Herein, the light absorption layer 35 may be formed in a grid pattern. The light absorption layer 35 may include a first light absorption layer 35A and a second light absorption layer 35B. The first light absorption layer 35A may contact the plurality of first color filters 34A. The second light absorption layer 35B may be formed to overlap the pluralities of second and third color filters 34B and 34C, which will be subsequently formed. Also, the first light absorption layer 35A may be as high as the plurality of first color filters 34A, and the second light absorption layer 35B may be lower than the first light absorption layer 35A in height.

The plurality of first color filters 34A and the light absorption layer 35 are formed as follows. To form the plurality of first color filters 34A and the light absorption layer 35 on the back side B of the substrate 30, a first photoresist (not shown) is applied and then a first color filter mask pattern (not shown) and a light absorption layer mask pattern (not shown) are formed. Herein, the first color filter mask pattern (not shown) and the light absorption layer mask pattern (not shown) are separately presented for the sake of convenience in description, and one mask pattern may be divided according to its disposition structure. The first color filter mask pattern (not shown) may be formed corresponding to a first unit pixel region 301, and the light absorption layer mask pattern (not shown) may be formed along the boundary of the unit pixel regions 301, 302, and 303. The light absorption layer mask pattern (not shown) may be formed in a grid pattern, and the light absorption layer mask pattern (not shown) may be formed thinner than the unit pixel regions 301, 302, and 303 by being formed smaller than the wavelength of exposure light.

Next, a light exposure and development process is performed using the first color filter mask pattern (not shown) and the light absorption layer mask pattern (not shown). Through the light exposure and development process, the first photoresist that is not exposed to light remains on the back side B of the substrate 30, and the first photoresist that is exposed to light is removed to selectively expose the back side B of the substrate 30. As a result, the plurality of first color filters 34A and the light absorption layer 35 are formed on the substrate 30.

The plurality of first color filters 34A may include a red color filter, a green color filter, or a blue color filter. For example, the plurality of first color filters 34A may include a blue color filter. The light absorption layer 35 may be formed of the same material as that of the first color filters 34A. Thus, if the plurality of first color filters 34A include a blue color filter, then the light absorption layer 35 may include a blue color filter.

Referring to FIGS. 3C and 4C, the plurality of second color filters 34B are formed on the back side B of the substrate 30. The plurality of second color filters 34B may be formed to overlap the plurality of first color filters 34A and the light absorption layer 35. Each of the plurality of second color filters 34B may have a line width greater than a line width of the unit pixel regions 301, 302, and 303. The second color filters 34B may be formed to overlap a portion of each of the plurality of first color filters 34A to have step height. The plurality of second color filters 34B may be higher than the plurality of first color filters 34A.

The plurality of second color filters 34B are formed as follows. The substrate 30 where the first color filters 34A and the light absorption layer 35 are formed is spin-coated with a second photoresist (not shown), and then a second color filter mask pattern (not shown) is formed over the second photoresist (not shown). Subsequently, the second photoresist (not shown) is partially exposed to light and developed by using the second color filter mask pattern (not shown). As a result, the second photoresist (not shown) that is not exposed to light remains on the back side B of the substrate 30, and the exposed second photoresist (not shown) is removed to selectively expose the surface of the plurality of first color filters 34A and the back side B of the substrate 30, thus forming the plurality of second color filters 34B over the substrate 30.

The plurality of second color filters 34B may include a red color filter, a green color filter, or a blue color filter. For example, the second color filters 34B may include a green color filter.

Referring to FIGS. 3D and 4D, the plurality of third color filters 34C are formed on the back side B of the substrate 30. The plurality of third color filters 34C may be formed to overlap the light absorption layer 35 and the plurality of second color filters 34B.

The plurality of third color filters 34C may have a line width that is greater than a line width of the unit pixel regions 301, 302, 303. The plurality of third color filters 34C may be formed to overlap a portion of each of the plurality of second color filter 34B to have a step height. The plurality of third color filters 34C may be higher than the plurality of second color filters 34B.

The plurality of third color filters 34C are formed as follows, The substrate 30 where the pluralities of first and second color filters 34A and 34B and the light absorption layer 35 are formed is spin-coated with a third photoresist (not shown), and then a third color filter mask pattern (not shown) is formed over the third photoresist (not shown). Subsequently, the third photoresist (not shown) is partially exposed to light and developed by using the third color filter mask pattern (not shown). As a result, the third photoresist (not shown) that is not exposed to light remains on the back side B of the substrate 30, and the exposed third photoresist (not shown) is removed to selectively expose the surface of the pluralities of first and second color filters 34A and 34B, thus forming the plurality of third color filters 34C over the substrate 30.

The plurality of third color filters 34C may include a red color filter, a green color filter, and a blue color filter. For example, the plurality of third color filters 34C may include a red color filter.

Referring to FIG. 3E, a planarization layer 36 is formed over the color filters 34. The planarization layer 36 may be formed of an oxide layer, a nitride layer, or an oxynitride layer.

Hemispheric micro-lenses 37 are formed over the planarization layer 36 to respectively correspond to the unit pixel regions 301, 302 and 303. The micro-lenses 37 may be formed to be spaced apart from each other to obtain optical shading characteristics.

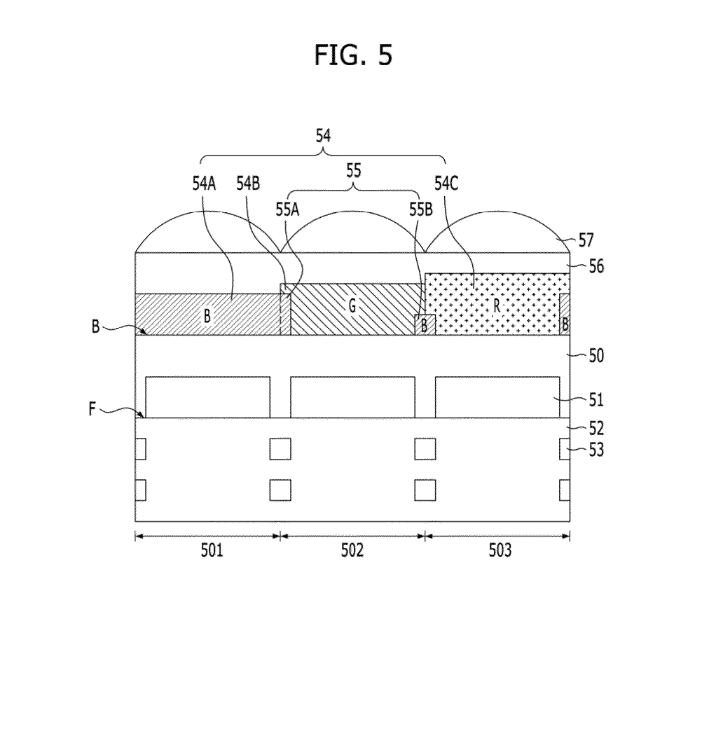

FIG. 5 is a cross-sectional view illustrating an exemplary.

Referring to FIG. 5, an exemplary image sensor includes a substrate 50 having a plurality of unit pixel regions 501, 502 and 503, a plurality of light receiving devices 51 formed in the substrate 50, an interlayer dielectric layer 52 formed on the front side F of the substrate 50 and including a signal generation circuit 53, a plurality of color filters 54 formed on the back side B of the substrate 50, which is the opposite side to the front side F, a light absorption layer 55 formed on the back side B of the substrate 50 under the color filters 54, a planarization layer 56 covering the color filters 54 in the upper portion of the back side B of the substrate 50, and micro-lenses 57 formed on the planarization layer 56.

The substrate 50 including the unit pixel regions 501, 502 and 503 may include a single crystalline material. The substrate 50 may include a silicon-containing material. Therefore, the substrate 50 may include single crystalline silicon.

The light receiving devices 51 are formed in the substrate 50 of the unit pixel regions 501, 502 and 503. The light receiving devices 51 may include photodiodes (PD). The photodiodes generate photocharges by using received light.

Subsequently, the multiple light receiving devices 51 and an isolation layer (not shown) for isolating the light receiving devices 51 from each other may be formed on the substrate 50.

The interlayer dielectric layer 52 is formed on the front side F of the substrate 50, and the signal generation circuit 53 is formed in the inside of the interlayer dielectric layer 52. The signal generation circuit 53 generates electrical signals corresponding to the charges generated in the light receiving devices 51. The signal generation circuit 53 may include a plurality of conductive lines and a plurality of transistors formed inside the interlayer dielectric layer 52. The plurality of transistors may include a transfer transistor, a reset transistor, a source follower transistor, a select transistor, or a bias transistor. Also, the plurality of multiple layers of conductive lines may be electrically connected to each other or may be electrically connected to the transistors through plugs.

The color filters 54 are formed in the upper portion of the back side B of the substrate 50. The color filters 54 may be formed corresponding to the unit pixel regions 501, 502 and 503. The color filters 54 may have different height according to wavelength. The color filters 54 may include the light absorption layer 55.

The color filters 54 may include a plurality of first color filters 54A, a plurality of second color filters 54B, and a plurality of third co or filters 54C. A first color filter 54A may contact a sidewall of the light absorption layer 55, and a second color filter 54B may be located on one side of the first color filter 54A. A third color filter 54C may be located on one side of the second color filter 54B. Also, ends of the second color filter 54B and the third color filter 54C may overlap the light absorption layer 55.

The color filters 54 may have an RGB structure. For example, the plurality of first color filters 54A may include a blue color filter, and the plurality of second color filters 54B may include a green color filter. The plurality of third color filters 54C may include a red color filter.

The light absorption layer 55 is formed on the back side B of the substrate 50 under the color filters 54. The light absorption layer 55 may prevent an optical crosstalk phenomenon between adjacent unit pixel regions. The light absorption layer 55 is formed along the boundary of the unit pixel regions 501, 502 and 503. The light absorption layer 55 may include a first light absorption layer 55A and a second light absorption layer 55B. The first light absorption layer 55A may be formed on the sidewall of the first color filters 54A. The second light absorption layer 55B may be formed to overlap the ends of the subsequent second and third color filters 54B and 54C.

The first light absorption layer 55A may have the same height as the first color filters 54A, and the second light absorption layer 55B may be lower than the first color filters 54A in height.

The light absorption layer 55 may be formed of any materials that may absorb visible lights. The light absorption layer 55 may include the same material as the first color filters 54A. For example, if the plurality of first color filters 54A include a blue color filter, then the light absorption layer 55 may include a blue color filter.

The planarization layer 56 is formed over the color filters 54. The planarization layer 56 may be formed of an oxide layer, a nitride layer, or an oxynitride layer.

The hemispheric micro-lenses 57 are formed over the planarization layer 56 to respectively correspond to the unit pixel regions 501, 502 and 501 The micro-lenses 57 may be formed to be spaced apart from each other to obtain optical shading characteristics.

With the light absorption layer 55, the image sensor having the above-described structure may be capable of preventing the optical crosstalk phenomenon between the adjacent unit pixel regions 501, 502 and 503.

Also, with the structure where the light absorption layer 55 overlaps the color filters 54, the image sensor may effectively prevent the optical crosstalk phenomenon between the adjacent unit pixel regions 101, 102 and 103 and thus effectively improve the photo-sensitivity of the image sensor.

According to the technology of the present invention, the optical crosstalk phenomenon between adjacent unit pixel regions may be prevented by forming a light absorption layer along the boundary o unit pixel regions.

Also, photo-sensitivity may be effectively improved by forming the light absorption layer to overlap color filters and thus preventing the optical crosstalk phenomenon between adjacent unit pixel regions.

Also, process margins are obtained by forming color filters to include a light absorption layer. Therefore, procedural complexity and the number of process steps may be reduced, cutting down on production cost.

While the present invention has been described with respect to the specific embodiments, it will be apparent to those skilled in the art that various changes and modifications may be made without departing from the spirit and scope of the invention as defined in the following claims.

What is claimed is:

1. An image sensor, comprising:
a substrate including a plurality of unit pixel regions;
a light absorption layer formed on the substrate; and
a plurality of color filters formed on the substrate, wherein at least one of the plurality color filters is formed over the light absorbing layer,
wherein the plurality of color filters include a first color filter and a second color filter, and wherein the first color filter overlaps an end of the second color filter.

2. The image sensor of claim 1, wherein the plurality of color filters and the light absorption layer include a red color filter, a green color filter, or a blue color filter.

3. The image sensor of claim 1, wherein a height of the first color filter is lower than a height of the second color filter.

4. The image sensor of claim 1, wherein the light absorption layer is formed along boundaries of the unit pixel regions.

5. The image sensor of claim 1, wherein the light absorption layer has a grid pattern.

6. The image sensor of claim 1, wherein the light absorption layer is formed of a same material as a material of the first color filter.

7. The image sensor of claim 1, wherein the light absorption layer is formed on a sidewall of the first color filter and overlaps an end of the second color filter.

8. The image sensor of claim 1, wherein a height of the light absorption layer is the same as a height of the first color filter.

9. The image sensor of claim 8, wherein the light absorption layer includes a blue color filter.

10. The image sensor of claim 8, wherein the light absorption layer is formed to overlap ends of the first color filter and the second color filter.

11. The image sensor of claim 8, wherein a height of the light absorption layer is lower than a height of the first color filter or the second color filter.

12. An image sensor, comprising:
a substrate including plurality of unit pixel regions;
a light absorption layer formed on the substrate; and
a plurality of color filters formed on the substrate, wherein at least some of the plurality of color filters are formed over the light absorption layer,
wherein the plurality of color filters include a first color filter, a second color filter, and a third color filter.

13. The image sensor of claim 12, wherein the first color filter overlaps an end of the second color filter,
the second color filter overlaps ends of the first color filter, and the third color filter, and
the third color filter overlaps an end of the second color filter.

14. The image sensor of claim 12, wherein a height of the first color filter is lower than a height of the second color filter, and the height of the second color filter is lower than a height of the third color filter.

15. The image sensor of claim 12, wherein each color filter, of the plurality of color filters, has a line width that is greater than a line width of the unit pixel regions.

16. The image sensor of claim 12, wherein the light absorption layer is formed along boundaries of the unit pixel regions.

17. The image sensor of claim 12, wherein the light absorption layer has a grid pattern.

18. The image sensor of claim 12, wherein the light absorption layer contacts a sidewall of the first color filter and overlaps ends of the second color filter and the third color filter.

19. The image sensor of claim 12, wherein a height of the light absorption layer is the same as a height of the first color filter is as high as the first color filter,
the light absorption layer overlaps ends of the second color filter and the third color filter, and
the height of the light absorption layer is less than heights of the second color filter or the third color filter.

20. The image sensor of claim 12, wherein the light absorption layer includes a same material as a material of the first color filter.
